(19) United States
(12) Patent Application Publication
(10) Pub. No.: US 2017/0292185 A1
(43) Pub. Date: Oct. 12, 2017

(54) VACUUM EVAPORATION APPARATUS AND METHOD FOR MAKING PATTERNED FILM

(71) Applicants: Tsinghua University, Beijing (CN); HON HAI PRECISION INDUSTRY CO., LTD., New Taipei (TW)

(72) Inventors: YANG WEI, Beijing (CN); SHOU-SHAN FAN, Beijing (CN)

(21) Appl. No.: 15/444,170

(22) Filed: Feb. 27, 2017

(30) Foreign Application Priority Data
Apr. 8, 2016 (CN) 201610215457.3

(51) Int. Cl. C23C 14/28; C23C 14/24; C23C 14/04

(52) U.S. Cl. CPC C23C 14/28; C23C 14/042; C23C 14/246

(57) ABSTRACT

A vacuum evaporation apparatus includes an evaporating source belt, a depositing substrate, a vacuum room, a laser beam source, and a mesh in the vacuum room. The mesh includes a first surface and a second surface. The first surface faces and is spaced from the laser beam source. The second surface faces the depositing substrate. A portion of the evaporating source belt is located between the laser beam source and the mesh. The portion of the evaporating source belt between the laser beam source and the mesh is parallel to and spaced from the depositing substrate.

### CROSS-REFERENCE TO RELATED APPLICATIONS

This application claims priority to Chinese Patent Application No. 201610215457.3, filed on Apr. 8, 2016, the disclosure of which is incorporated herein by reference.

### FIELD

The present disclosure relates to a vacuum evaporation apparatus and a method for making a patterned film.

### BACKGROUND

A vacuum evaporation is a process of heating an evaporating source in vacuum to gasify and then deposit the evaporating source material on a surface of a substrate to form a film. In order to form a uniform thin film, it is necessary to form a uniform gaseous evaporating material around the substrate. Conventionally, a complex gas guiding device is used to uniformly transfer the gaseous evaporating material to the surface of the depositing substrate.

### BRIEF DESCRIPTION OF THE DRAWINGS

Implementations of the present technology will now be described, by way of example only, with reference to the attached figures.

FIG. 1 is a front view of one embodiment of a vacuum evaporation apparatus.

FIG. 2 is a vertical view of one embodiment of a mesh.

FIG. 3 is a front view of one embodiment of the mesh, an evaporating source belt, and a laser beam source.

FIG. 4 is a side view of one embodiment of mesh supporters along a length of the evaporating source belt.

FIG. 5 is a functional block diagram of one embodiment of the vacuum evaporation apparatus.

FIG. 6 is a vertical view of one embodiment of a depositing substrate and the laser beam source.

FIG. 7 is a scanning electron microscope (SEM) image of a carbon nanotube film drawn from a carbon nanotube array.

FIG. 8 is a SEM image of a carbon nanotube film structure.

FIG. 9 and FIG. 10 are SEM images of one embodiment of the evaporating source under different resolutions.

FIG. 11 is a SEM of one embodiment of the evaporating source belt after evaporation.

FIG. 12 is a SEM image of one embodiment of a patterned film.

FIG. 13 is an X-ray diffraction (XRD) image of one embodiment of the patterned film.

FIG. 14 is a flowchart of one embodiment of a method for making a patterned film.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one”.

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to illustrate details and features of the present disclosure better.

Several definitions that apply throughout this disclosure will now be presented.

The term “comprise” or “comprising” when utilized, means “include or including, but not necessarily limited to”; it specifically indicates open-ended inclusion or membership in the so-described combination, group, series, and the like.

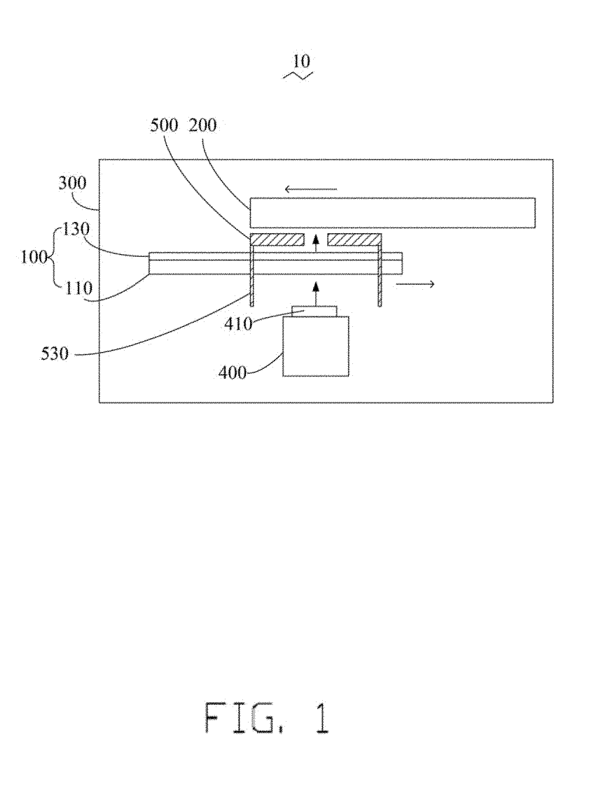

Referring to FIG. 1, one embodiment provides a vacuum evaporation apparatus 10. The vacuum evaporation apparatus 10 comprises an evaporating source belt 100, a depositing substrate 200, a vacuum room 300, a laser beam source 400, and a mesh 500. The evaporating source belt 100, the depositing substrate 200, the laser beam source 400, and the mesh 500 are located in the vacuum room 300.

The evaporating source belt 100 comprises a carbon nanotube film structure 110 and an evaporating material 130. The carbon nanotube film structure 110 is a carrying structure for the evaporating material 130. The evaporating material 130 is located on a surface of the carbon nanotube film structure 110.

The mesh 500 includes a first surface and a second surface. The first surface faces and is spaced from the laser beam source 400. The second surface faces the depositing substrate 200. A portion of the evaporating source belt 100 is located between the laser beam source 400 and the mesh 500. The portion of the evaporating source belt between the laser beam source 400 and the mesh 500 is parallel with and spaced from the depositing substrate 200. The depositing substrate 200 faces and is spaced from the evaporating source belt. A distance between the depositing substrate 200 and the evaporating source belt 100 is in a range from about 1 micrometer to about 10 millimeters.

The evaporating source belt 100 is capable of moving along a length direction between the laser beam source 400 and the mesh 500. The laser beam source 400 can emit a laser beam to irradiate the portion of the evaporating source belt 100 between the laser beam source 400 and the mesh 500. Thus, the evaporating material 130 on the portion of the evaporation source belt 100 between the laser beam source 400 and the mesh 500 is gasified and deposited on a depositing surface of the depositing substrate 200 to form a thin film. When the evaporating source belt 100 moves along the length direction between the laser beam source 400 and the mesh 500, another portion of the evaporating source belt 100 facing the laser beam source 400 can be irradiated by the laser beam source 400, thereby, the evaporating material 130 on the different portions of the evaporation source belt 100 can be gasified.

In one embodiment, the evaporating source belt 100, the laser beam source 400 and the mesh 500 are simultaneously moved relative to the depositing substrate 200 to form a plurality of thin films at different locations on the depositing surface of the depositing substrate 200. The plurality of thin films forms a patterned film.

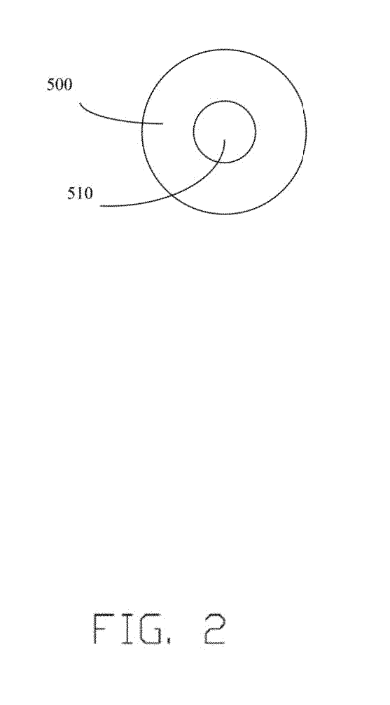

Referring to FIG. 2, the mesh 500 includes at least one through hole 510. A gaseous evaporating material 130 can passes through the through hole 510 to reach the depositing surface of the depositing substrate 200. In one embodiment, the thickness of the mesh 500 is in a range from about 1 micrometer to about 5 millimeters. The through hole 510 may have a required shape and size. The gaseous evaporating material 130 is instantly adhered to the depositing surface of the depositing substrate 200 to form a patterned film after passing through the through hole 510. A pattern of the patterned film is corresponding to the required shape and size of the through hole 510 of the mesh 500. A number, shape, and size of the through hole 510 are not limited to, can be designed according to need. The location of the through hole 510 in the mesh 500 is corresponding to the required location of the patterned film formed on the depositing surface of the depositing substrate 200. In one embodiment, the mesh 500 is sandwiched between and in direct contact with the depositing surface of the depositing substrate 200 and the evaporating source belt 100. In another embodiment, the mesh 500 are respectively spaced from the depositing surface of the depositing substrate 200 and the evaporating source belt 100.

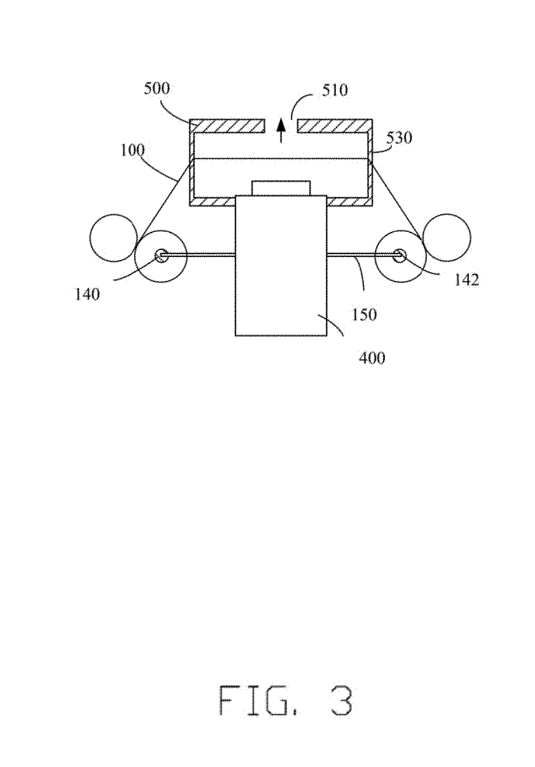

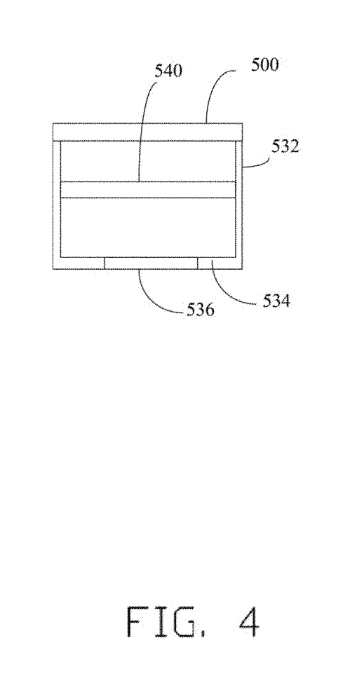

Referring to FIG. 3 and FIG. 4, during a movement of the evaporation source belt 100, the mesh 500 and the laser beam source 400 are disposed at a fixed location. In one embodiment, the vacuum evaporation apparatus 10 includes a mesh supporter 530. The mesh supporter 530 is used to connect and fix the mesh 500 and the laser beam source 400. The mesh supporter 530 can include two first supporters 532 and a second supporter 534. Two first supporters 532 are respectively disposed on two opposite ends of the mesh 500 and perpendicular to the mesh 500. The second supporter 534 is parallel to the mesh 500 and connected to two first supporters 532. The second supporter 534 includes a hole 536 corresponding to a shape of the end of the laser beam source 400 and can be attached to the end of the laser beam source 400. In another embodiment, the vacuum evaporation apparatus 10 includes an evaporating source belt supporter 540. The position of the evaporating source belt 100 between the laser beam source 400 and the mesh 500 includes a first end and a second end along the length direction. The evaporating source belt supporter 540 supports the first end and the second end. The evaporating source belt supporter 540 and the mesh supporter 530 are fixedly connected. The evaporating source belt supporter 540 is formed of two cylindrical cross beams parallel to each other, and the evaporating source belt supporter 540 is parallel to the mesh 500. The two cylindrical cross beams are respectively connected to the two first supporters 532. An evaporating source belt supporter 540 length direction is perpendicular to the evaporating source belt 100 length direction when the evaporating source belt 100 passes through a space between the laser beam source 400 and the mesh 500 along the length direction. A length of the evaporating source belt supporter 540 is greater than or equal to a width of the evaporating source belt 100.

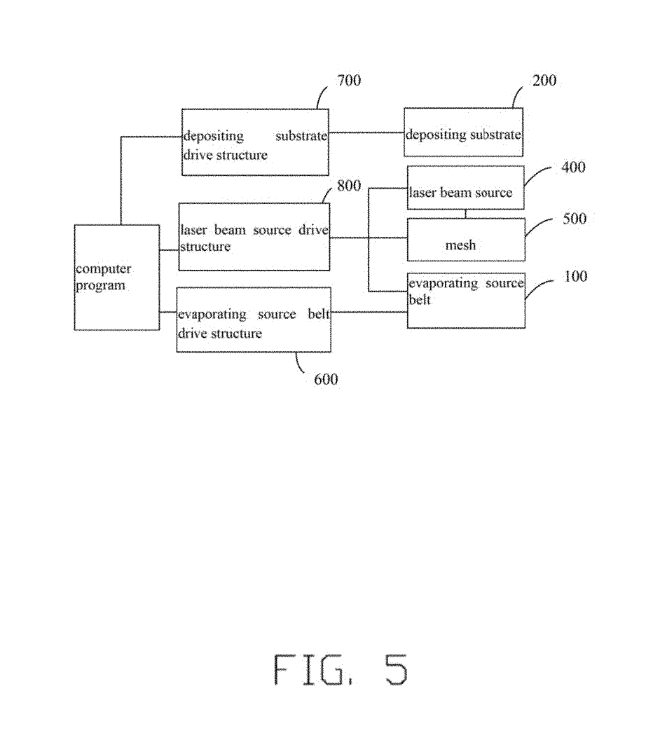

Referring to FIG. 5, the vacuum evaporation apparatus 10 can include an evaporating source belt drive structure 600. The evaporating source belt drive structure 600 can drive the evaporating source belt 100 passing through the space between the laser beam source 400 and the mesh 500 along the length direction. In one embodiment, the evaporating source belt drive structure 600 may include a plurality of gears and a motor. The evaporating source belt 100 passes between the plurality of gears, and the plurality of the gears are driven by the motor to drive the evaporation source belt 100 forward.

The portion of the evaporating source belt 100 between the laser beam source 400 and the mesh 500 is irradiated by the laser beam during vacuum deposition, and the other portion of the evaporating source belt 100 can be carried by a carrying structure. The carrying structure can be connected to the laser beam source 400. Although the evaporating source belt 100 moves relative to the mesh 500 and the laser beam source 400, a location of the evaporating source belt 100 is fixed relative to a location of the mesh 500 and laser beam source 400. Thus, the evaporating source belt 100, the mesh 500 and the laser beam source 400 as a whole is displaced relative to the depositing substrate 200, and the patterned film can be formed at different locations on the depositing surface of the depositing substrate 200. In one embodiment, the carrying structure may include a first reel 140 and a second reel 142. An axial direction of the first reel 140 and an axial direction of the second reel 142 are parallel to each other and parallel to the mesh 500. The first reel 140 and the second reel 142 are respectively connected to the laser beam source 400 through a connecting rod 150. The evaporating source belt 100 includes a third end and a fourth end along the length direction. The third end is connected to the first reel 140, and the fourth end is connected to the second reel 142. The evaporating source belt 100 wounds around at least one reel between the first reel 140 and the second reel 142. The length direction of the evaporating source belt 100 is perpendicular to the axial direction of the first reel 140 and the second reel 142. The evaporating source belt drive structure 600 drives the evaporating source belt 100 moves from the first reel 140 toward the second reel 142 during the vacuum evaporation process or moves from the second reel 142 toward the first reel 140 during the vacuum evaporation process.

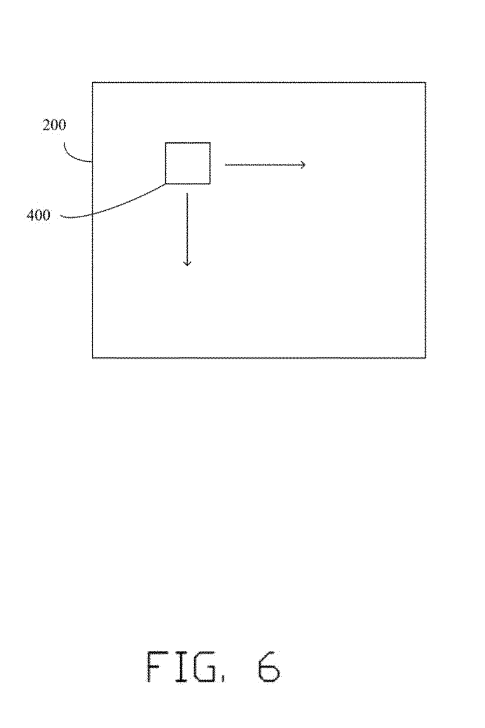

Referring to FIG. 6, the evaporating source belt 100, the mesh 500 and the laser beam source 400 as a whole can have a relative motion with the depositing substrate 200. In one embodiment, the evaporating source belt 100, the mesh 500 and the laser beam source 400 as a whole can move, when the location of the depositing substrate 200 keeps unchanged. In another embodiment, the depositing substrate 200 moves when the evaporating source belt 100, the mesh 500 and the laser beam source 400 as a whole keeps still. In yet another embodiment, the evaporating source belt 100, the mesh 500, the laser beam source 400 and the depositing substrate 200 simultaneously move.

The vacuum evaporation apparatus 10 can include a depositing substrate drive structure 700. The depositing substrate drive structure 700 can drive the depositing substrate 200 to move in an arbitrary direction parallel to the mesh 500. A movement direction, a movement distance and a movement time of the depositing substrate 200 can be controlled by a computer program to form a required patterned film on the depositing surface of the depositing substrate 200.

The vacuum evaporation apparatus 10 can include a laser beam source drive structure 800. The evaporating source belt 100, the laser beam source 440, and the mesh 500 as a whole can be driven to move in an arbitrary direction parallel to the depositing substrate 200 by the laser beam source drive structure 800. A movement direction, a movement distance and a movement time of the whole formed by the evaporating source belt 100, the laser beam source 440, and the mesh 500 can be controlled by a computer program to form a required patterned film on the depositing surface of the depositing substrate 200.

The evaporating source belt 100 includes a carbon nanotube film structure 110 and an evaporating material 130. The carbon nanotube film structure 110 is a belt structure. The evaporating material 130 is disposed on a surface of the carbon nanotube film structure 110. The carbon nanotube film structure 110 is capable of forming a free-standing structure, can be suspended by supporters. The evaporating material 130 is located on a surface of the suspended carbon nanotube film structure 110. The carbon nanotube film structure 110 coated by the evaporating material 130 is facing to and spaced from the depositing surface of the depositing substrate 200. A distance between the depositing surface of the depositing substrate 200 and the carbon nanotube film structure 110 is in a range from about 1 micrometer to about 10 millimeters.

The carbon nanotube film structure 110 is a resistive element. The carbon nanotube film structure 110 has a small heat capacity per unit area and has a large specific surface area but a minimal thickness. In one embodiment, the heat capacity per unit area of the carbon nanotube film structure 110 is less than 2×10⁻⁴ J/cm²·K. In another embodiment, the heat capacity per unit area of the carbon nanotube film structure 110 is less than 1.7×10⁻⁶ J/cm²·K. The specific surface area of the carbon nanotube film structure 110 is larger than 200 m²/g. The thickness of the carbon nanotube film structure 110 is less than 100 micrometers. The laser beam source 400 inputs a laser signal to the carbon nanotube film structure 110. Since the carbon nanotube film structure 110 has the small heat capacity per unit area, the carbon nanotube film structure 110 can convert the laser signal to heat quickly, and a temperature of the carbon nanotube film structure 110 can rise rapidly. Since the carbon nanotube film structure 110 has the large specific surface area and is very thin, the carbon nanotube film structure 110 can rapidly transfer heat to the evaporating material 130. The evaporating material 130 is rapidly heated to evaporation or sublimation temperature.

The carbon nanotube film structure 110 comprises a single carbon nanotube film or at least two stacked carbon nanotube films. The carbon nanotube film comprises a plurality of carbon nanotubes. The plurality of carbon nanotubes are generally parallel to each other and arranged substantially parallel to a surface of the carbon nanotube film structure 110. The carbon nanotube film structure 110 has a uniform thickness. The carbon nanotube film can be regarded as a macro membrane structure. In the macro membrane structure, an end of one carbon nanotube is joined to another end of an adjacent carbon nanotube arranged substantially along the same direction by Van der Waals attractive force. The carbon nanotube film structure 110 and the carbon nanotube film have a macro area and a microscopic area. The macro area denotes a membrane area of the carbon nanotube film structure 110 or the carbon nanotube film when the carbon nanotube film structure 110 or the carbon nanotube film is regarded as a membrane structure. In terms of a microscopic area, the carbon nanotube film structure 110 or the carbon nanotube film is a network structure having a large number of carbon nanotubes joined end to end. The microscopic area signifies a surface area of the carbon nanotubes is actually carrying the evaporating material 130.

In one embodiment, the carbon nanotube film is formed by drawing from a carbon nanotube array. This carbon nanotube array is grown on a growth surface of a substrate by a chemical vapor deposition method. The carbon nanotubes in the carbon nanotube array are substantially parallel to each other and perpendicular to the growth surface of the substrate. Adjacent carbon nanotubes make mutual contact and combine by van der Waals forces. By controlling the growth conditions, the carbon nanotube array is substantially free of impurities such as amorphous carbon or residual catalyst metal particles. When carbon nanotube fragments (CNT fragments) are drawn, adjacent carbon nanotubes are continuously drawn out end to end by van der Waals forces to form a free-standing and uninterrupted macroscopic carbon nanotube film. The carbon nanotube array made of carbon nanotubes drawn end to end is also known as a super-aligned carbon nanotube array. In order to grow the super-aligned carbon nanotube array, the growth substrate material can be a P-type silicon, an N-type silicon, or a silicon oxide substrate.

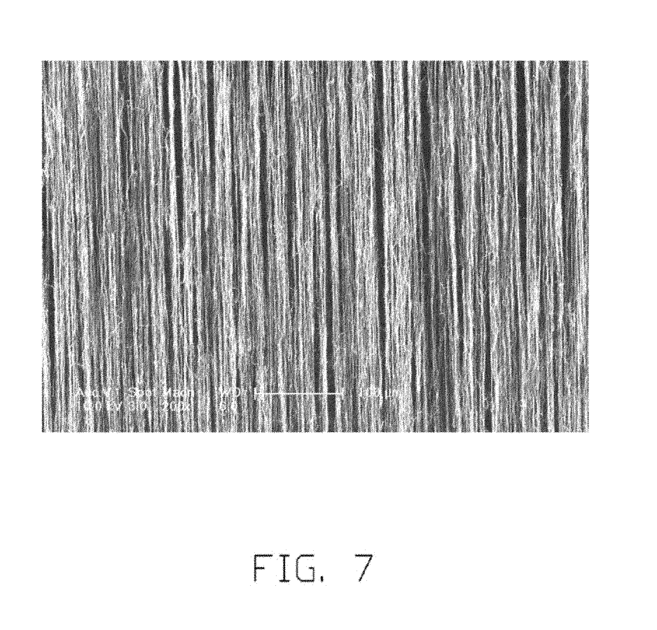

The carbon nanotube film includes a plurality of carbon nanotubes that can be joined end to end and arranged substantially along the same direction. Referring to FIG. 7, a majority of carbon nanotubes in the carbon nanotube film can be oriented along a preferred orientation, meaning that a large number of the carbon nanotubes in the carbon nanotube film are arranged substantially along the same direction. An end of one carbon nanotube is joined to another end of an adjacent carbon nanotube arranged substantially along the same direction by Van der Waals attractive force. A small number of the carbon nanotubes are randomly arranged in the carbon nanotube film and has a small if not negligible effect on the larger number of the carbon nanotubes in the carbon nanotube film arranged substantially along the same direction.

More specifically, the carbon nanotube drawn film includes a plurality of successively oriented carbon nanotube segments joined end-to-end by Van der Waals attractive force therebetween. Each carbon nanotube segment includes a plurality of carbon nanotubes substantially parallel to each other and joined by Van der Waals attractive force therebetween. The carbon nanotube segments can vary in width, thickness, uniformity, and shape. The carbon nanotubes in the carbon nanotube drawn film are also substantially oriented along a preferred orientation.

Microscopically, the carbon nanotubes oriented substantially along the same direction may not be perfectly aligned in a straight line, and some curve portions may exist. It can be understood that some carbon nanotubes located substantially side by side and oriented along the same direction in contact with each other cannot be excluded. The carbon nanotube film includes a plurality of gaps between the adjacent carbon nanotubes so that the carbon nanotube film can have better transparency and higher specific surface area.

The carbon nanotube film is capable of forming a free-standing structure. The term “free-standing structure” can be defined as a structure that does not require a substrate for support. For example, a free standing structure can sustain the weight of itself when it is hoisted by a portion thereof without any damage to its structural integrity. So, if the carbon nanotube drawn film is placed between two separate supporters, a portion of the carbon nanotube film, not in contact with the two supporters, would be suspended between the two supporters and yet maintain film structural integrity. The free-standing structure of the carbon nanotube film is realized by the successive carbon nanotubes joined end to end by Van der Waals attractive force.

The carbon nanotube film has a small and uniform thickness in a range from about 0.5 nm to 10 microns. Since the carbon nanotube film drawn from the carbon nanotube array can form the free-standing structure only by van der Waals forces between the carbon nanotubes, the carbon nanotube film has the large specific surface area. In one embodiment, the specific surface area of the carbon nanotube film measured by the BET method is in a range from about 200 m²/g to 2600 m²/g. A mass per unit area of the carbon nanotube film is in a range from about 0.01 g/m² to about 0.1 g/m² (area here refers to the macro area of the carbon nanotube film). In another embodiment, the mass per unit area of the carbon nanotube film is about 0.05 g/m². Since the carbon nanotube film has a minimal thickness and the heat capacity of the carbon nanotube is itself small, the carbon nanotube film has small heat capacity per unit area. In one embodiment, the heat capacity per unit area of the carbon nanotube film is less than 2×10⁻⁴ J/cm²·K.

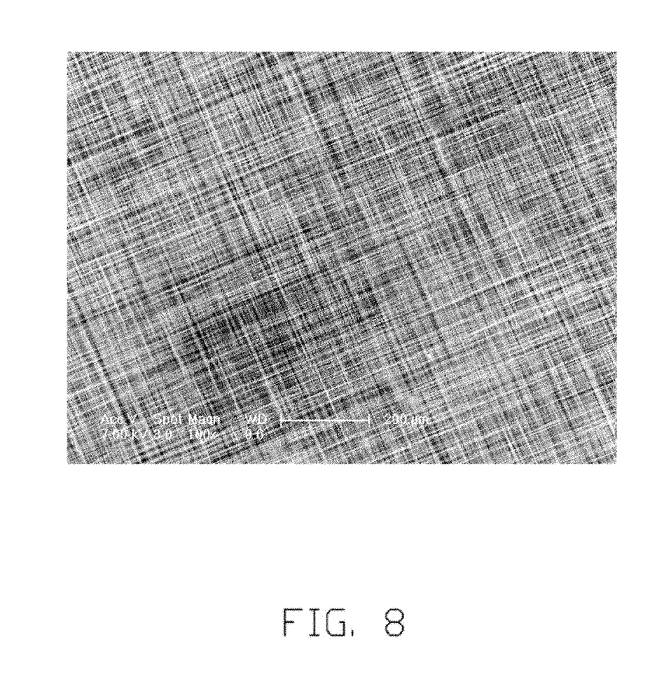

The carbon nanotube film structure 110 may include at least two stacked carbon nanotube films. In one embodiment, a number of layers of the stacked carbon nanotube film is 50 layers or less. In another embodiment, the number of layers of the stacked carbon nanotube film is 10 layers or less. Additionally, an angle can exist between the orientation of carbon nanotubes in adjacent carbon nanotube films. Adjacent carbon nanotube films can be combined by only Van der Waals attractive forces therebetween without the need of an adhesive. An angle between the aligned directions of the carbon nanotubes in two adjacent carbon nanotube films can range from about 0 degrees to about 90 degrees. In one embodiment, referring to FIG. 8, the carbon nanotube film structure includes at least two stacked carbon nanotube films, and the angle between the aligned directions of the carbon nanotubes in the two adjacent carbon nanotube films is 90 degrees.

The evaporating material 130 is adhered and coated on the surface of the carbon nanotube film structure 110. Macroscopically, the evaporating material 130 can be seen as a layer formed on at least one surface of the carbon nanotube film structure 110. In one embodiment, the evaporating material 130 is coated on two surfaces of the carbon nanotube film structure 110. The evaporating material 130 and the carbon nanotube film structure 110 form a composite membrane. In one embodiment, a thickness of the composite membrane is 100 microns or less. In another embodiment, the thickness of the composite membrane is 5 microns or less. Because an amount of the evaporating material 130 carried per unit area of the carbon nanotube film structure 110 is small, in microscopic terms a morphology of the evaporating material 130 may be nanoscale particles or layers with nanoscale thickness, being attached to a single carbon nanotube surface, the surfaces of a few carbon nanotubes or a surface of the composite material layer. In one embodiment, the morphology of the evaporating material 130 is particles. A diameter of the particles is in a range from about 1 nanometer to about 500 nanometers. In another embodiment, the morphology of the evaporating material 130 is a layer. A thickness of the evaporating material 130 is in a range from about 1 nanometer to 500 nanometers. The evaporating material 130 can completely cover and coat the surface of the composite material layer or a single carbon nanotube for all or part of its length. The morphology of the evaporating material 130 coated on the surface of the carbon nanotube composite membrane 110 is associated with the amount of the evaporating material 130, species of the evaporating material 130, a wetting performance of the carbon nanotubes, and other properties. For example, the evaporation material 130 is more likely to be particle when the evaporation material 130 is not soaked in the surface of the carbon nanotube or the surface of the composite material layer. The evaporating material 130 is more likely to uniformly coat a single carbon nanotube surface to form a continuous layer when the evaporating material 130 is soaked in the surface of carbon nanotubes or the surface of the composite material layer. In addition, when the evaporating material 130 is an organic material having high viscosity, it may form a continuous film on the surface of the carbon nanotube film structure 110. No matter what the morphology of the evaporating material 130 may be, the amount of evaporating material 130 carried by per unit area of the carbon nanotube film structure 110 is small. Thus, the laser signal inputted by the laser beam source 400 can instantaneously and completely gasify the evaporating material 130. In one embodiment, the evaporating material 130 is completely gasified within 1 second. In another embodiment, the evaporating material 130 is completely gasified within 10 microseconds. The disposition of the evaporating material 130 on the surface of the carbon nanotube film structure 110 is uniform so that different locations of the carbon nanotube film structure 110 carry substantially equal amounts of the evaporating material 130. Since the carbon nanotube film structure 110 is a free-standing structure and flexible, the evaporation source belt 100 is still flexible after coating the evaporating material 130 and can be wound on a reel.

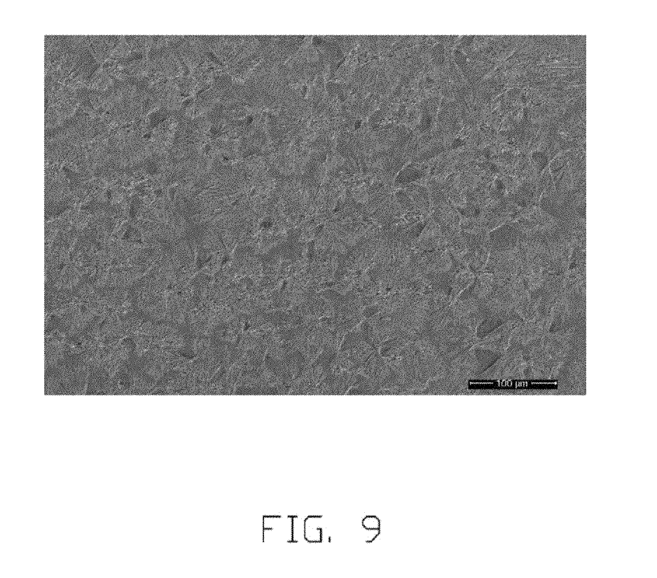

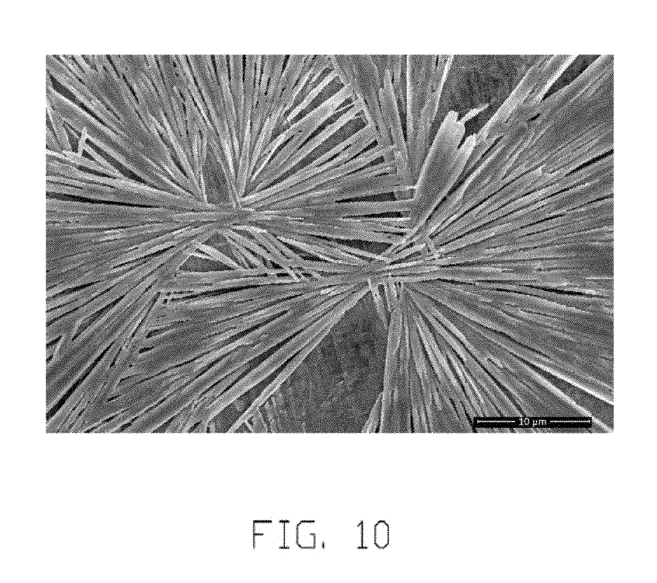

A gasification temperature of the evaporating material 130 is lower than a gasification temperature of the carbon nanotube under same conditions. The evaporating material 130 does not react with the carbon in the vacuum evaporation process. In one embodiment, the evaporating material 130 is an organic material, and a gasification temperature of the organic material is less than or equal to 300□. The evaporating material 130 may be a single material or may be a mixture of a plurality of materials. The evaporating material 130 can be uniformly disposed on the surface of the carbon nanotube film structure 110 by a plurality of methods, such as solution method, vapor deposition method, plating method, or chemical plating method. In one embodiment, the evaporating material 130 is previously dissolved or uniformly dispersed in a solvent to form a solution or dispersion. The solution or dispersion is uniformly attached to the carbon nanotube film structure 110. The solvent evaporates, leaving the dried evaporating material uniformly coated on the surfaces of the carbon nanotube film structure 110. When the evaporating material 130 includes a mixture of a plurality materials, the plurality of materials can be dissolved in a liquid phase solvent and mixed a required ratio in advance so that the plurality of materials can be coated on different locations of the carbon nanotube film structure 110 in the required ratio. Referring FIGS. 9 and 10, in one embodiment, the evaporating material 130 formed on the carbon nanotube film structure 110 is a mixture of methylammonium iodide and lead iodide, and the methylammonium iodide and the lead iodide are uniformly mixed in the mixture.

The laser beam source 400 includes an emitter 410. The emitter 410 faces to and is spaced from the through hole 510 of the mesh 500. The laser beam source 400 generates the laser signal and inputs the laser signal to the surface of the carbon nanotube film structure 110. The frequency range of the laser signal comprises radio waves, infrared, visible light, ultraviolet light, microwaves, X-rays or γ-rays. A wavelength of the optical signal can be selected in a range from ultraviolet wavelength to far infrared wavelength. An average power density of the electromagnetic signal is in a range from about 100 mW/mm² to 20 W/mm². In one embodiment, the laser beam source 400 is a pulse laser generator. The laser beam source 400 further includes an optical fiber having a first optical fiber end connected to the emitter 410 and a second optical fiber end connected to a laser. The laser can be disposed outside of the vacuum room 300. The laser signal emitted by the laser is transmitted to inside of the vacuum room 300 by the optical fiber and irradiated to the evaporating source belt 100. A distance between the laser beam source 400 and the carbon nanotube film structure 110 is not limited, as long as the laser signal emitted from the laser beam source 400 can be transmitted to the surface of the carbon nanotube film structure 110.

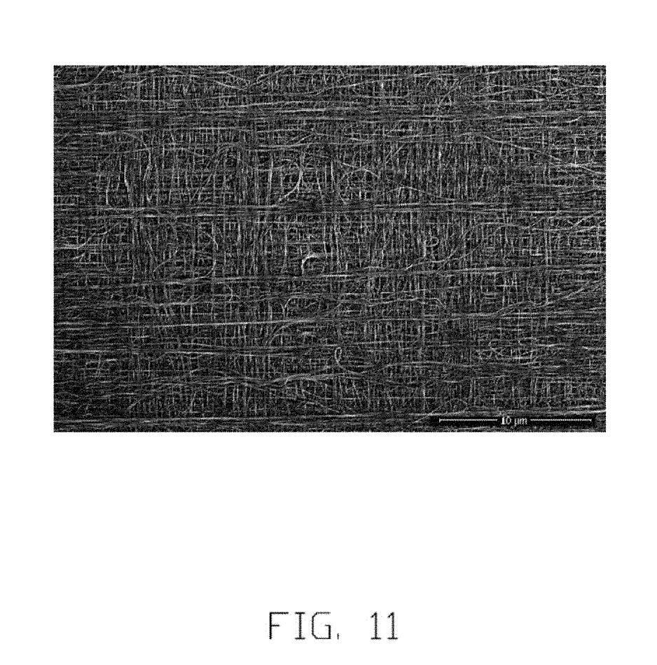

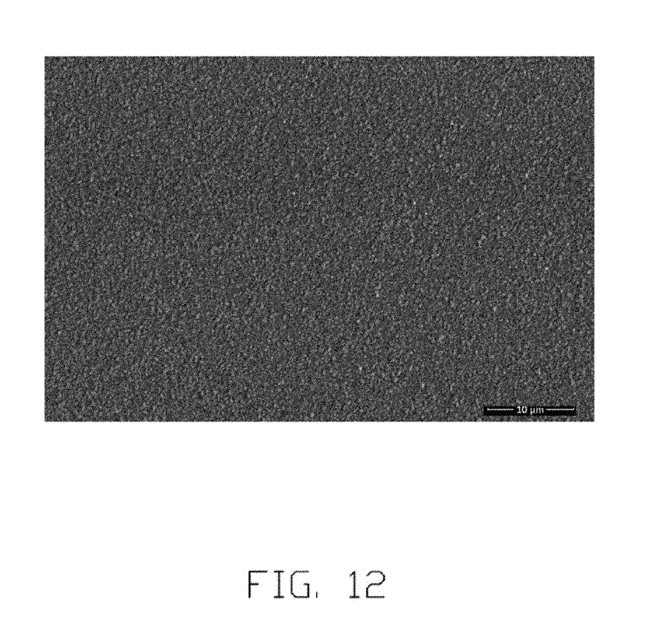

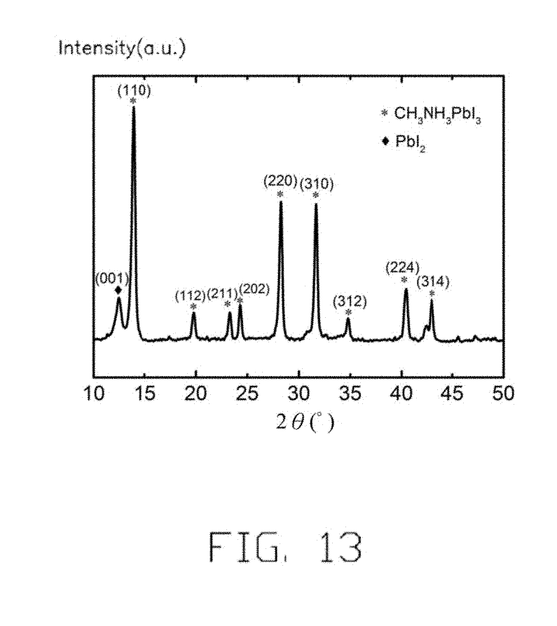

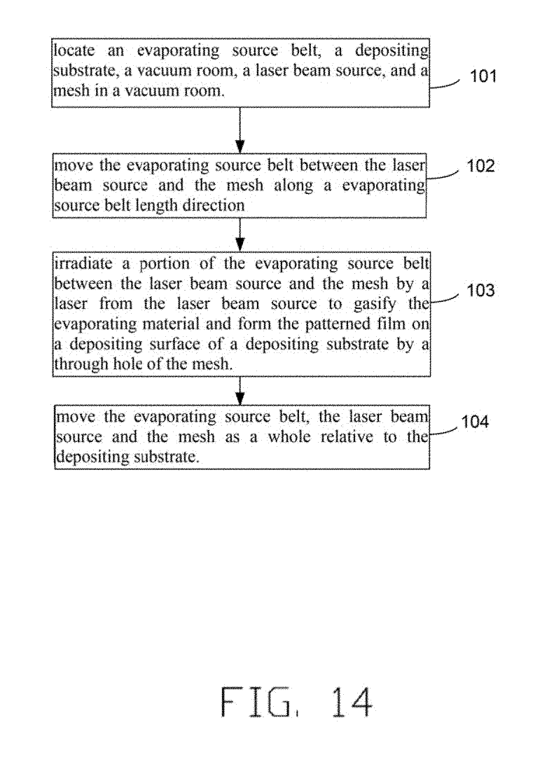

The laser beam source 400 inputs the laser signal to the carbon nanotube film structure 110. Since the carbon nanotube film structure 110 has the small heat capacity per unit area, and the temperature of the carbon nanotube film structure 110 can rise rapidly. Since the carbon nanotube film structure 110 has the large specific surface area and is very thin, the carbon nanotube film structure 110 can rapidly transfer heat to the evaporating material 130. The evaporating material 130 is rapidly heated to evaporation or sublimation temperature. Since per unit area of the carbon nanotube film structure 110 carries a small amount of the evaporating material 130, all the evaporating material 130 may instantly gasify. The carbon nanotube film structure 110 and the depositing substrate 200 are parallel to and spaced from each other. In one embodiment, the distance between the depositing substrate 200 and the carbon nanotube film structure 110 is in a range from about 1 micrometer to about 10 millimeters. Since the distance between the carbon nanotube film structure 110 and the depositing substrate 200 is small, a gaseous evaporating material 130 evaporated from the carbon nanotube film structure 110 can rapidly pass through the through hole 510 of the mesh 500 and attach to the depositing surface of the depositing substrate 200 to form a patterned film. The area of the depositing surface of the depositing substrate 200 is equal or less than the macro area of the carbon nanotube film structure 110. The laser beam source 400 heats the portion of the evaporation source belt 100 between the mesh 500 and the laser beam source 400. The evaporating material 130 disposed on the position of the carbon nanotube film structure 110 will form a vapor depositing film on the depositing surface of the depositing substrate 200 corresponding to the position of the carbon nanotube film structure 110 after evaporation. Since the evaporating material 130 is uniformly carried by the carbon nanotube film structure 110, the patterned film is also a uniform structure. Referring FIG. 11 and FIG. 12, in one embodiment, after irradiating the evaporating source belt 100 by laser, the temperature of the carbon nanotube film structure 110 rises quickly, the mixture of the methylammonium iodide and the lead iodide disposed on the surface of the carbon nanotube film structure 110 is instantly gasified, and a perovskite structure CH₃NH₃PbI₃ film is formed on the depositing surface of the depositing substrate 200. FIG. 11 shows a structure of the evaporating source belt 100 after laser irradiation. After evaporating the evaporating material 130 disposed on the surface structure of the carbon nanotube film structure 110, the carbon nanotube film structure 110 retains the original network structure, and the carbon nanotubes of the carbon nanotube film structure 110 are still joined end to end. FIG. 12 shows that the methylammonium iodide and the lead iodide continue a chemical reaction after gasification, and form a thin film having a uniform thickness on the depositing surface of the depositing substrate 200. Referring to FIG. 13, the thin film can be tested by XRD (X-ray diffraction). The XRD can determine and show as patterns that a material of the thin film is the perovskite structure CH₃NH₃PbI₃.

The evaporating source belt 100 can move relative to the laser beam source 400 and the mesh 500 in the length direction. After the evaporation source belt 100 being irradiated and the evaporating material 130 coated on the evaporation source belt 100 between the laser beam source 400 and the mesh 500 being evaporated, the evaporation source belt 100 may be moved along the length direction and the evaporating source belt 100 between the laser beam source 400 and the mesh 500 un-irradiated faces to the emitter 410 of the laser beam source 400. When the evaporating source belt 100 moves, the depositing substrate 200 also moves. Thus, a new depositing surface of the depositing substrate 200 faces to the mesh 500. A movement distance and a movement direction of the depositing substrate 200 are not limited. In one embodiment, a required pattern can be inputted into the computer by a program, and the laser beam source 400 continuously irradiates the evaporating source belt 100 between the laser beam source 400 and the mesh 500 in the length direction to form the patterned film on the depositing substrate 200.

A flowchart is presented in accordance with an example embodiment as illustrated. The embodiment of a method for making a patterned film is provided by way of example, as there are a plurality of ways to carry out the method. A first example described below can be carried out using the configurations illustrated in FIGS. 1 to 13 for example and various elements of these figures are referenced in explaining the first example. Each block represents one or more processes, methods, or subroutines carried out in the first example. Additionally, the illustrated order of blocks is by example only, and the order of the blocks can be changed. The first example can begin at block 101. Depending on the embodiment, additional steps can be added, others removed, and the ordering of the steps can be changed.

At block 101, an evaporating source belt 100, a depositing substrate 200, a vacuum room 300, a laser beam source 400, and a mesh 500 are located in a vacuum room 300. The evaporating source belt 100 comprises an evaporating material 130 and a carbon nanotube film structure 110. The carbon nanotube film structure 110 is a carrying structure for the evaporating material 130. The evaporating material 130 is located on a surface of the carbon nanotube film structure 110. The mesh 500 includes a first surface and a second surface. The first surface is faced to and spaced from the laser beam source 400. The second surface faces the depositing substrate 200. A portion of the evaporating source belt 100 between the laser beam source 400 and the mesh 500 is parallel to and spaced from the depositing substrate 200.

At block 102, the evaporating source belt 100 is moved between the laser beam source 400 and the mesh 500 along a length direction.

At block 103, the portion of the evaporating source belt 100 between the laser beam source 400 and the mesh 500 is irradiated by laser from the laser beam source 400 to gasify the evaporating material 130 and form a patterned film on a depositing surface of a depositing substrate 200 by a through hole of the mesh 500.

At block 101, a method for fabricating the evaporating source belt 100 includes the steps of: (11) providing the carbon nanotube film structure 110; (12) disposing the evaporating material 130 on the surface of the carbon nanotube film structure 110.

In step (11), the carbon nanotube film structure 110 is suspended by a supporter.

In step (12), the evaporating material 130 is disposed on the surface of the carbon nanotube film structure 110 by a plurality of methods, such as solution method, vapor deposition method, plating method or chemical plating method. The vapor deposition method may be chemical vapor deposition (CVD) method or physical vapor deposition (PVD) method.

A solution method for disposing the evaporating material 130 on the surface of the carbon nanotube film structure 110 includes the steps of: (121) dissolving or uniformly dispersing the evaporating material 130 in a solvent to form a solution or dispersion; (122) uniformly attaching the solution or dispersion to the carbon nanotube film structure 110 by spray coating method, spin coating method, or dip coating method; (123) evaporating and drying the solvent to make the evaporating material 130 uniformly attach on the surface of the carbon nanotube film structure 110.

When the evaporating material 130 includes a plurality of materials, the plurality of materials can be dissolved in a liquid phase solvent and mixed with a required ratio in advance so that the plurality of materials can be disposed in different locations of the carbon nanotube film structure 110 by the required ratio.

The depositing substrate 200 and the evaporating source belt 100 are faced to and spaced from each other. In one embodiment, a distance between the depositing surface of the depositing substrate 200 and the carbon nanotube film structure 110 of the evaporating source belt 100 is substantially equal. The carbon nanotube film structure 110 is substantially parallel to the depositing surface of the depositing substrate 200, and the area of the depositing surface of the depositing substrate 200 is equal or less than the macro area of the carbon nanotube film structure 110. Thus, a gaseous evaporating material 130 can reach the depositing surface of the depositing substrate 200 substantially at the same time. In one embodiment, an evaporating source belt supporter 540 is disposed on the mesh 500. The evaporating source belt 100 can be suspended and parallel to the depositing surface of the depositing substrate 200 by the evaporating source belt supporter 540. The mesh 500 may be respectively parallel to the depositing surface of the depositing substrate 200 and the carbon nanotube film structure 110.

At block 102, the evaporating source belt 100 can be moved between the laser beam source 400 and the mesh 500 along the length direction by an evaporating source belt drive structure 600. In one embodiment, the evaporating source belt drive structure 600 may include a plurality of gears and a motor. The plurality of the gears is driven by the motor to make the evaporation source belt 100 move forward.

At block 103, the carbon nanotubes can uniformly absorb the laser. An average power density of a laser signal is in a range from about 100 mW/mm² to 20 W/mm². Since the carbon nanotube film structure 110 has the small heat capacity per unit area, the carbon nanotube film structure 110 can quickly generate a thermal response to rising temperature when the carbon nanotube film structure 110 absorbs the laser signal. Since the carbon nanotube film structure 110 has the large specific surface area, the carbon nanotube film structure 110 can quickly exchange heat with surrounding medium, and heat signals generated by the carbon nanotube film structure 110 can quickly heat the evaporating material 130. Since the amount of the evaporating material 130 disposed on per unit macro area of the carbon nanotube film structure 110 is small, the evaporating material 130 can be completely gasified instantly by the heat signals. Therefore, the evaporating material 130 can reach and disposed on locations of the depositing surface of the depositing substrate 200 corresponding to locations of the evaporating material 130 disposed on the surface of the carbon nanotube film structure 110. Since the amount of the evaporating material 130 disposed on different locations of the carbon nanotube film structure 110 is same (the evaporating material 130 is uniformly disposed on the carbon nanotube film structure 110), the patterned film formed on the depositing surface of the depositing substrate 200 has a uniform thickness. Thus, thickness and uniformity of the patterned film are related to the amount and uniformity of the evaporating material 130 disposed on the carbon nanotube film structure 110. When the evaporating material 130 includes a plurality of materials, a proportion of the plurality of materials is same in different locations of the carbon nanotube film structure 110. Thus, the plurality of materials still has same proportion in the gaseous evaporating material 130; a uniform patterned film can be formed on the depositing surface of the depositing substrate 200.

Because the gaseous evaporating material 130 can only pass through the through hole 510 in the mesh 500 to reach the depositing surface of the depositing substrate 200, the location of the depositing surface of the depositing substrate 200 corresponding to the through hole 510 in the mesh 500 can form the patterned film. The pattern of the patterned film is corresponding to the pattern of the through hole 510. When the material of the evaporating material 130 is the organic material, it is difficult to form the patterned film by the conventional mask etching method, such as photoetching method. Further, the conventional photoetching method is difficult to achieve high accuracy to form the patterned film. In the method for making the patterned film, the patterned film can be once formed on the depositing surface of the depositing substrate 200 by using the mesh 500 having a required pattern. Thus, the patterned film with high accuracy can be formed by eliminating the process of the conventional mask etching.

The method for making the patterned film can further includes a block 104. In the block 104, the evaporating source belt 100, the laser beam source 400 and the mesh 500 as a whole is moved relative to the depositing substrate 200. In the block 104, the depositing surface used to form the patterned film is disposed opposite to the mesh 500. When the evaporating material 130 disposed on the evaporating source belt 100 is irradiated by the laser beam source 400, the evaporating material 130 can be evaporated and passed through the through hole 510 of the mesh 500 to adhere on the depositing surface of the depositing substrate 200 to form the patterned film.

In one embodiment, the depositing substrate 200 can move by a depositing substrate drive structure 700. In another embodiment, the evaporating source belt 100, the laser beam source 400 and the mesh 500 as a whole can have a relative motion with the depositing substrate 200 by a laser beam source drive structure 800. In yet another embodiment, the depositing substrate 200 can move by a depositing substrate drive structure 700, and the evaporating source belt 100, the laser beam source 400 and the mesh 500 as a whole can have a relative motion with the depositing substrate 200 by a laser beam source drive structure 800.

Steps of the block 102 and the block 104 may be performed alternately or simultaneously. The laser beam source 400 irradiates different locations of the evaporating source belt 100 when the evaporating source belt 100 moves between the laser beam source 400 and the mesh 500 along the length direction. Since the depositing surface of the depositing substrate 200 faces to the mesh 500, a required pattern can be formed on the depositing surface to form a patterned film.

The carbon nanotube film is a free-standing structure and used to carry the evaporating material and composite material layer. The carbon nanotube film has a large specific surface area and a good uniformity so that the evaporating material carried by the carbon nanotube film can uniformly distribute on the carbon nanotube film before evaporation. The carbon nanotube film can be heated instantaneously by a laser signal. Thus the evaporating material can be completely gasified in a short time to form a uniform gaseous evaporating material distributed in a large area. The distance between the depositing substrate and the carbon nanotube film is small. Thus the evaporating material carried on the carbon nanotube film can be substantially utilized to save the evaporating material and improve the deposition rate. The carbon nanotube film is flexible and can form an evaporating source belt with the evaporating material. The evaporating source belt can continuously move between a laser beam source and the depositing substrate. Thus, the evaporating material can be continuously deposited and printed on a depositing surface of the depositing substrate to form a patterned vacuum-evaporated film.

Even though numerous characteristics and advantages of certain inventive embodiments have been set out in the foregoing description, together with details of the structures and functions of the embodiments, the disclosure is illustrative only. Changes may be made in detail, especially in matters of arrangement of parts, within the principles of the present disclosure to the full extent indicated by the broad general meaning of the terms in which the appended claims are expressed.

Depending on the embodiment, certain of the steps of methods described may be removed, others may be added, and the sequence of steps may be altered. It is also to be understood that the description and the claims drawn to a method may comprise some indication in reference to certain steps. However, the indication used is only to be viewed for identification purposes and not as a suggestion as to an order for the steps.

The embodiments shown and described above are only examples. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A vacuum evaporation apparatus comprising:
an evaporating source belt comprising an evaporating material and a carbon nanotube film structure, wherein the evaporating material is located on a surface of the carbon nanotube film structure;
a laser beam source;
a depositing substrate faces and is spaced from the evaporating source belt;
a mesh comprising a first surface and a second surface, wherein the first surface faces and is spaced from the laser beam source, the second surface faces the depositing substrate, a portion of the evaporating source belt is located between the laser beam source and the mesh, and the portion of the evaporating source belt between the laser beam source and the mesh is parallel to and spaced from the depositing substrate; and
a vacuum room, wherein the evaporating source belt, the depositing substrate, the laser beam source, and the mesh are located in the vacuum room.

2. The vacuum evaporation apparatus of claim 1, further comprising an evaporating source belt drive structure, wherein the evaporating source belt drive structure is configured to drive the evaporating source belt to pass through a space between the laser beam source and the mesh along a evaporating source belt length direction.

3. The vacuum evaporation apparatus of claim 1, further comprising a depositing substrate drive structure, wherein the depositing substrate drive structure is configured to drive the depositing substrate to move in an arbitrary direction parallel to the mesh.

4. The vacuum evaporation apparatus of claim 1, further comprising a laser beam source drive structure, wherein the laser beam source drive structure is configured to drive the evaporating source belt, the laser beam source, and the mesh as a whole to move in an arbitrary direction parallel to the depositing substrate.

5. The vacuum evaporation apparatus of claim 1, further comprising a mesh supporter, wherein the mesh supporter connects and fixes the mesh and the laser beam source.

6. The vacuum evaporation apparatus of claim 5, wherein the mesh supporter comprises two first supporters and a second supporter, the two first supporters are respectively disposed on two ends of the mesh and perpendicular to the mesh, and the second supporter is parallel to the mesh and connected to the two first supporters.

7. The vacuum evaporation apparatus of claim 1, further comprising a first reel and a second reel, wherein the first reel and the second reel are respectively connected to the laser beam source through a connecting rod.

8. The vacuum evaporation apparatus of claim 7, wherein an evaporating source belt length direction is perpendicular to an axial direction of the first reel and the second reel.

9. The vacuum evaporation apparatus of claim 8, wherein the evaporating source belt comprises a third end and a forth end along the evaporating source belt length direction, the third end is connected to the first reel, and the forth end is connected to the second reel.

10. The vacuum evaporation apparatus of claim 1, wherein a heat capacity per unit area of the carbon nanotube film structure is less than 2×10⁻⁴ J/cm²·K, and a specific surface area of the carbon nanotube film structure is larger than 200 m²/g.

11. The vacuum evaporation apparatus of claim 1, wherein the carbon nanotube film structure comprises at least one carbon nanotube film, and the at least one carbon nanotube film comprises a plurality of carbon nanotubes joined end to end by Van der Waals attractive force.

12. The vacuum evaporation apparatus of claim 1, wherein a thickness of the evaporating source belt is less than or equal to 100 micrometers.

13. The vacuum evaporation apparatus of claim 1, wherein a distance between the depositing substrate and the evaporating source belt is in a range from about 1 micrometer to about 10 millimeters.

14. A method for making a patterned film comprising:
S1, locating an evaporating source belt, a depositing substrate, a vacuum room, a laser beam source, and a mesh in a vacuum room, wherein the evaporating source belt comprises an evaporating material and a carbon nanotube film structure, and the evaporating material is located on a surface of the carbon nanotube film structure; the mesh comprises a first surface and a second surface, the first surface faces and is spaced from the laser beam source, and the second surface faces the depositing substrate;
S2, moving the evaporating source belt between the laser beam source and the mesh along a evaporating source belt length direction; and
S3, irradiating a portion of the evaporating source belt between the laser beam source and the mesh by a laser from the laser beam source to gasify the evaporating material and form the patterned film on a depositing surface of a depositing substrate by a through hole of the mesh.

15. The method of claim 14, further comprising a step of S4, wherein the step of S4 comprises moving the evaporating source belt, the laser beam source and the mesh as a whole relative to the depositing substrate.

16. The method of claim 14, wherein a method for fabricating the evaporating source belt comprising:
S11, providing the carbon nanotube film structure; and
S12, disposing the evaporating material on a surface of the carbon nanotube film structure by solution method, vapor deposition method, plating method or chemical plating method.

17. The method of claim 16, wherein the solution method for disposing the evaporating material on the surface of the carbon nanotube film structure comprising:
S121, dispersing the evaporating material in a solvent to form a solution or dispersion;
S122, attaching the solution or dispersion to the carbon nanotube film structure; and
S123, drying the solvent to make the evaporating material uniformly attach on the surface of the carbon nanotube film structure.

18. The method of claim 14, wherein the evaporating material comprises a plurality of materials, and the plurality of materials are dissolved in a liquid phase solvent and mixed with each other.

19. The method of claim 14, wherein a thickness of the evaporating source belt is less than or equal to 100 micrometers.

20. The method of claim 14, wherein a heat capacity per unit area of the carbon nanotube film structure is less than 2×10⁻⁴ J/cm²·K, and a specific surface area of the carbon nanotube film structure is larger than 200 m²/g.
